(19) United States
(12) Patent Application Publication
(10) Pub. No.: US 2010/0052771 A1
(43) Pub. Date: Mar. 4, 2010

(54) CIRCUIT FOR DRIVING MULTIPLE CHARGE PUMPS

(76) Inventor: Hendrik Hartono, San Jose, CA (US)

Correspondence Address: PERKINS COIE LLP;PATENT-SEA, P.O. BOX 1247, SEATTLE, WA, 98111-1247, US

(21) Appl. No.: 12/202,064

(22) Filed: Aug. 29, 2008

(51) Int. Cl. G05F 1/10; H03L 7/06

(52) U.S. Cl. 327/536; 327/157

(57) ABSTRACT

A system for driving multiple charge pumps in a single unit is disclosed. The charge pump system includes a set of multiple charge pumps arranged in parallel. The charge pumps are connected to a clock signal generator, which generates clock signals that direct the charging of the charge pumps and are offset in time from one another. The clock signals may be generated such that rising edges of the clock signals are separated by a specified time interval. The clock signals may be generated by a ring oscillator using signals provided by stages of the oscillator to generate the multiple signals. The clock signals may also be generated by providing a single input clock signal to a multi-phase generator, which outputs a set of clock signals having different phases based on the input clock signal. The system may also be configured to generate the offset clock signals using other methods, such as using a programmed microcontroller or using spread spectrum techniques.

### BACKGROUND

In designing electrical circuits, availability of power sources at the proper voltage is an important consideration. In general, circuits are powered by a single power source that may be located some distance from the components being powered. In addition, some components may need power supplied at a voltage different from the voltage supplied by the main power supply. A charge pump is a standard component to solve this problem. However, for the charge pump to be useful, it must provide consistent voltage over a period of time regardless of the components receiving the voltage. In particular, peak current is an issue in cases where the power and ground buses are limited. If attached components draw excessive amounts of current, the voltage on the power bus may drop below the specified value. This drop will depend upon the bus resistance. Although this drop may be acceptable for the charge pump circuit itself, it could potentially cause problems for other components that are attached to the charge pump, such as latches and flip-flops. In addition, after the current from the charge pump has been used, it must be returned to ground, which has the potential to create a ground bounce. Thus, it would be useful to have techniques to create a more stable and dependable charge pump system.

### BRIEF DESCRIPTION OF THE DRAWINGS

FIG. 1 illustrates a circuit suitable for implementing the charge pump system.

FIG. 2A illustrates a voltage-controlled ring oscillator circuit suitable for generating a plurality of output clock signals.

FIG. 2B illustrates a buffer circuit suitable for tapping clock signals from the stages of the ring oscillator circuit.

FIG. 3 illustrates an alternate circuit suitable for operating a plurality of charge pumps using a multi-phase generator.

FIG. 4 illustrates a four-phase generator circuit implemented using D flip-flops.

FIG. 5 illustrates an example timing diagram of the signals associated with the four-phase generator.

### DETAILED DESCRIPTION

A system for driving multiple charge pumps in a single unit is disclosed (hereinafter referred to as the “charge pump system”). The charge pump system includes a set of multiple charge pumps arranged in parallel. The charge pumps are connected to a clock signal generator, which generates clock signals that direct the charging of the charge pumps. In order to reduce the peak demand on the power supply, the clock signals are arranged so that they are offset in time from one another. For example, the signals may be generated such that rising edges of the clock signals are separated by a specified time interval. In one configuration for generating the clock signals, the voltage controlled oscillator comprises a ring oscillator using an inverter chain. In this configuration, the system generates multiple clock signals by using intermediate signals from the inverter chain to provide a sequence of clock signals. In an alternate configuration, the voltage controlled oscillator provides a single input clock signal to a multi-phase generator, which outputs a set of clock signals having different phases based on the input clock signal. The system may also be configured to generate the offset clock signals using other methods, such as using a programmed microcontroller or using spread spectrum techniques.

Various embodiments of the invention will now be described. The following description provides specific details for a thorough understanding and an enabling description of these embodiments. One skilled in the art will understand, however, that the invention may be practiced without many of these details. Additionally, some well-known structures or functions may not be shown or described in detail, so as to avoid unnecessarily obscuring the relevant description of the various embodiments. The terminology used in the description presented below is intended to be interpreted in its broadest reasonable manner, even though it is being used in conjunction with a detailed description of certain specific embodiments of the invention.

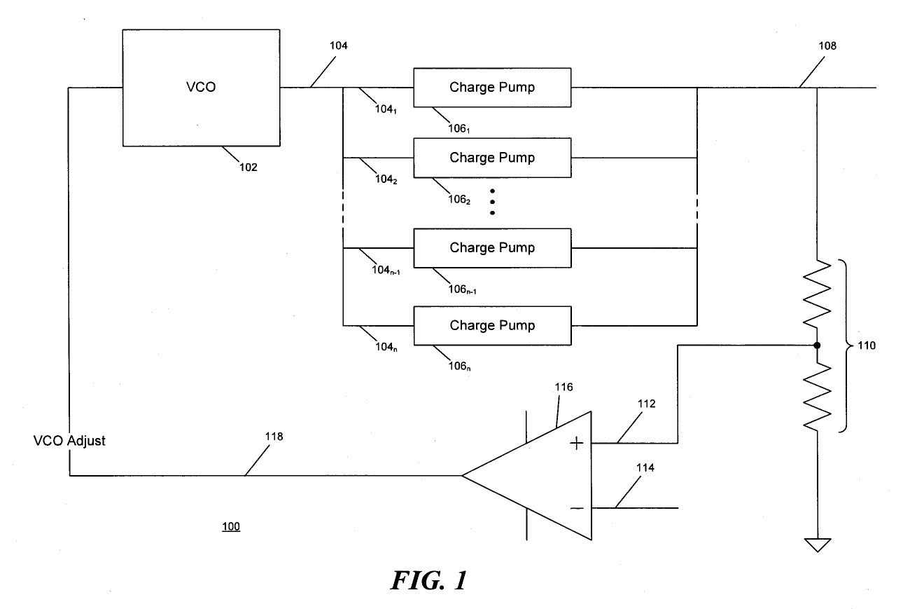

FIG. 1 illustrates a circuit 100 suitable for implementing the charge pump system. The circuit 100 includes a voltage-controlled oscillator (VCO) 102, which is configured to generate multiple clock signals 104. The multiple clock signals 104 are provided as separate signals 104₁-104ₙ to a set of charge pumps 106₁-106_{n.} In a charge pump, a set of switches are used to connect a power supply to a capacitor (called the “flying capacitor”). The switches are connected to an oscillator (such as VCO 102), which causes subsets of the switches to alternately open and close to achieve the desired output voltage in the capacitor. When a load is connected to the charge pump, current flows from the capacitor, powering the load and reducing the voltage of the charge pump. In the circuit 100, the charge pumps 106₁-106ₙ are connected in parallel to increase the current that can be provided by the charge pump circuit without substantially reducing the voltage. In the charge pump system, the clock signals 104₁-104ₙ are generated so that they are offset in time by a predetermined duration (i.e. the clock signals 104₁-104ₙ are out of phase with each other by a predetermined amount). By offsetting the clock signals 104₁-104_{n,} the charge pump system reduces the maximum power drawn from the power bus at a given time, reducing the drop in the power bus when the charge pumps are charged. The offset similarly reduces the problem of ground bounce.

The charge pumps 106₁-106ₙ are configured to generate an output voltage 108. The output voltage 108 may be connected to other components (not shown) to make use of the provided voltage. The output voltage 108 is also used in a feedback loop to regulate the VCO 102. In the feedback loop, the output voltage 108 is provided to a voltage divider 110, which generates a comparison voltage signal 112. The comparison voltage signal 112 is provided as an input to a comparator 116. The comparator 116 compares the comparison voltage signal 112 to a reference voltage 114 and outputs a VCO adjustment signal 118 based on the comparison.

The VCO adjustment signal 118 is provided as a feedback signal to the VCO 102. The VCO 102 may then adjust the rate of its clock in response to the feedback signal. If the charge pumps 106₁-106ₙ are over-pumping, the VCO adjustment signal 118 directs the VCO 102 to reduce the clock frequency. In contrast, if a current load is attached to the charge pump output 108, the feedback loop will adjust the frequency of the VCO 102 higher in order to maintain the output voltage 108 at the desired level. One skilled in the art will appreciate that the generation of the VCO adjustment signal 118 can be controlled by varying the reference voltage 114 or the components of the voltage divider 110. The adjustment signal could also be generated using other means, such as by using a microcontroller programmed to generate a VCO adjustment signal 118 by digitally comparing the output voltage 108 to the reference signal 114 or to a stored reference value.

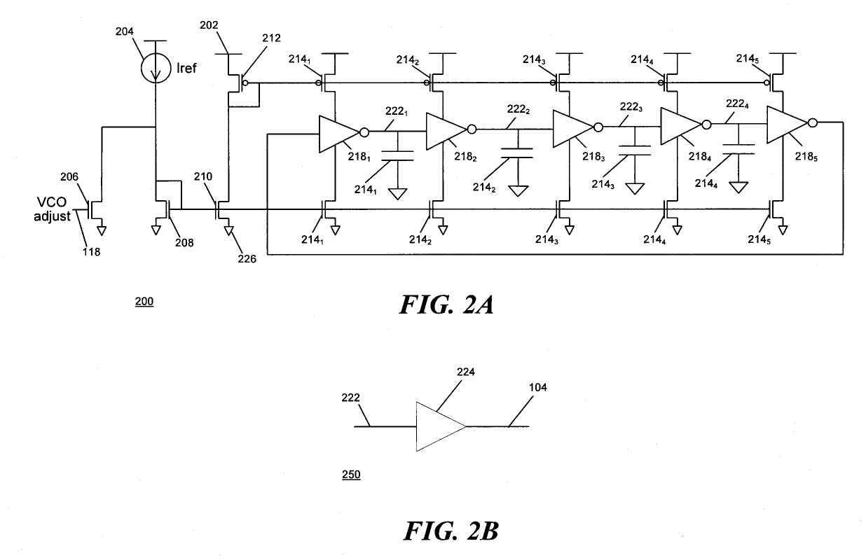

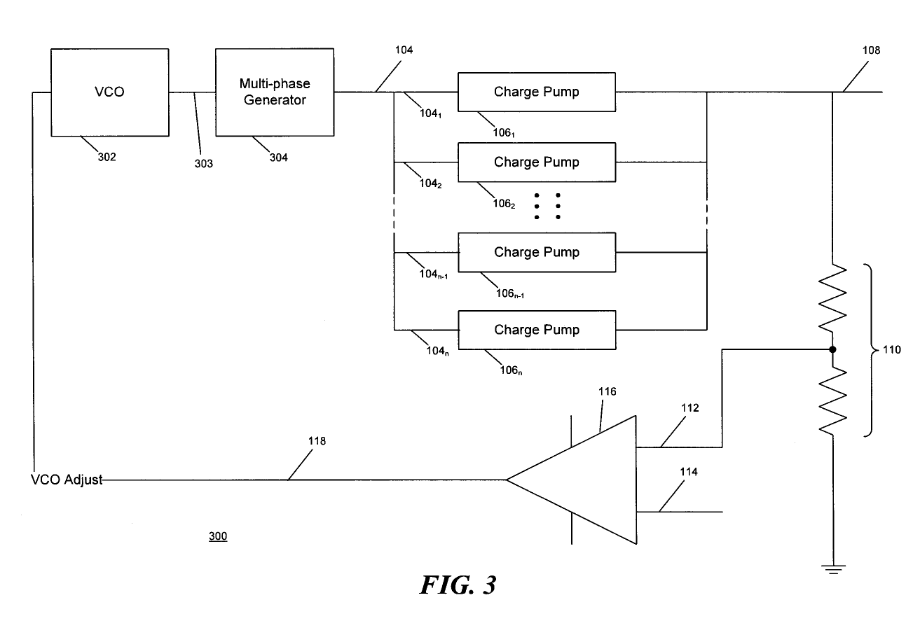

FIG. 2A illustrates a voltage-controlled ring oscillator circuit 200 suitable for generating a plurality of output clock signals 104. The ring oscillator circuit 200 is connected to a supply voltage 202 and a low voltage 226. The low voltage 226 may be connected to ground or may be set to a defined low voltage, such as the inverse of the supply voltage 202. The ring oscillator circuit 200 also includes a current source 204, which produces a constant current I_{ref}.

The ring oscillator circuit 200 receives the VCO adjustment signal 118 at the feedback transistor 206. The drain of the feedback transistor 206 is connected to the current source 204, while the source of the feedback transistor 206 is connected to the low voltage 226 or to ground. The ring oscillator circuit 200 also includes a transistor 208, which has its gate and drain terminals connected together. The gate terminal of the transistor 208 is connected to the gate terminals of transistors 210 and 214₁-214₅. Transistor 208 in combination with each of the transistors 210 and 214₁-214₅ forms a set of six separate current mirrors. Thus, for each of the transistors 210 and 214₁-214₅, the current flowing between source and drain is equal to the current flowing between the source and drain of transistor 208 if the component transistors are equivalent. Transistor parameters may also be varied so that the current flowing through transistors 210 and 214₁-214₅ is proportional to the input current. The generated current is provided to transistor 212 and to inverters 218₁-218₅.

Similarly, transistor 212 has its drain and gate terminals connect together. The gate terminal of transistor 212 is connected to the gate terminals for transistors 216₁-216₅. The combination of transistor 212 with each of the transistors 216₁-216₅ forms a set of p-type current mirrors. Therefore, the current flowing between source and drain of transistors 216₁-216₅ is equal to the current flowing between source and drain of transistor 212. As discussed above, this current is equal to (or proportional to) the current through transistor 208.

The ring oscillator circuit 200 includes at its core a group of five inverters 218₁-218₅. Each of the inverters 218₁-218₅ has its output connected to the input of the following inverter. The output of inverter 218₅ is then connected to the input of transistor 218₁, forming a ring. A pulse entering into inverter 218₁ is output in inverted form. This inverted signal is then input into inverter 218₂, which outputs the original signal pulse. This sequence is repeated through every inverter in the ring. Because each inverter has a known delay, the output of a selected inverter is a signal having a regular sequence of pulses, which can be used as a clock signal. The delay of the inverters can be controlled by varying the current or voltage input into the power and ground or high and low voltage terminals of the inverters 218₁-218₅.

As discussed above, the input current into the high and low terminals of the inverters is controlled by the current that passes through transistor 208. Transistor 208 is connected in parallel with feedback transistor 206, which is controlled by the VCO adjustment signal 118. The VCO adjustment signal 118 determines whether transistor 206 is enabled or disabled. When the feedback transistor 206 is disabled, the current from the current source 204 passes entirely through transistor 208, which provides the maximum available current to the control terminals of the inverters 218₁-218₅. However, if the VCO adjustment signal 118 controls the feedback transistor 206 to enable it, some of the current from the current source 204 will pass through the feedback transistor 206, reducing the current provided to the terminals of the inverters 218₁-218₅. In this way, the VCO adjustment signal controls the rate at which the clock pulses propagate through the ring oscillator.

In a ring oscillator circuit 200 according to the present system, the circuit generates multiple clock pulses by tapping the signal at the output of one or more of the inverters 218 in the ring oscillator chain. For example, in the displayed circuit 200, clock signals could be generated by tapping the signals 222₁-222₄, at the outputs of the inverters 218₁-218₅. As shown in FIG. 2A, the inverters 218₁-218₅ are also connected to the low voltage (or ground) through capacitors 220₁-220₄. The capacitors 220₁-220₄ operate as low pass filters to filter the higher frequency components of the signals 222₁-222₄ passing through the inverter chain.

FIG. 2B illustrates a buffer circuit 250 suitable for tapping clock signals from the stages of the ring oscillator circuit 200. The buffer circuit 250 may be connected to an output of the oscillators 218₁-218₅. The output signal 222 from the inverter 218 is provided to the input of a buffer 224. The buffer 224 then generates an output clock signal 104 (FIG. 1). The buffer 224 is used to separate the output signal 104 from the internals of the ring oscillator circuit 200. Buffer circuits 250 may be connected to the outputs of multiple inverters to generate multiple clock signals.

Thus, the ring oscillator circuit 200 of FIG. 2A can generate up to five separate clock signals by tapping the individual stages of the inverter chain. The generated clock signals will be equal to each other in duration but delayed with respect to each other based on the delay through each of the inverters 218₁-218₅. The ring oscillator circuit 200 could be configured to generate additional clock signals by adding additional inverters to the inverters 218₁-218₅ and connecting additional buffer circuits 250 to the outputs of the inverters.

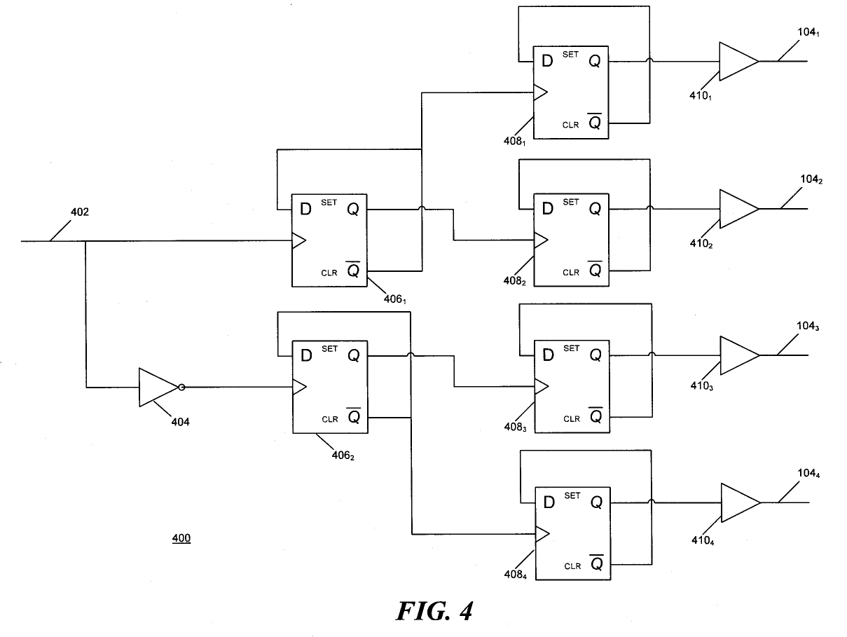

FIG. 3 illustrates an alternate circuit 300 suitable for operating a plurality of charge pumps using a multi-phase generator. The circuit 300 operates similarly to the circuit 100 described in FIG. 1. In particular, the circuit 300 includes a plurality of charge pumps 106₁-106_{n,} with each charge pump 106₁-106ₙ receiving a clock signal 104₁-104_{n.} The charge pumps 106₁-106ₙ generate an output voltage 108. The circuit 300 also includes a voltage divider 110, which generates a control voltage 112 that is provided to the comparator 116. The comparator 116 compares the control voltage 112 to the reference voltage 114 to generate the VCO adjustment signal 118.

Unlike the circuit 100 of FIG. 1, the circuit 300 in FIG. 3 includes a voltage controlled oscillator 302 which generates a single clock signal 303. The clock signal 303 is provided as an input to a multi-phase generator 304. The multi-phase generator 304 generates multiple output clock signals 104 from the clock signal 303. The output clock signals 104 are offset in time from each other by an amount depending on the configuration of the multi-phase generator 304. In one implementation, a four-phase generator is used, but any type of multi-phase generator could be used. For example, systems having 8- or 16-charge pumps could include an 8- or 16-phase generator (respectively) to generate the source oscillator signals. Alternatively, the system could be configured to cascade multiple stages of multi-phase generators to generate clock signals further separated in time.

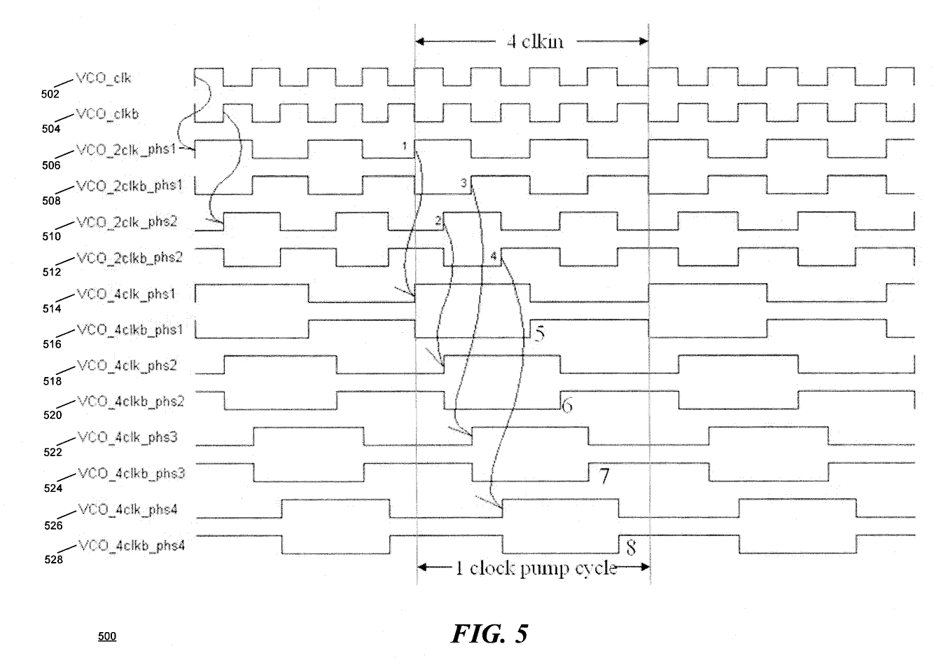

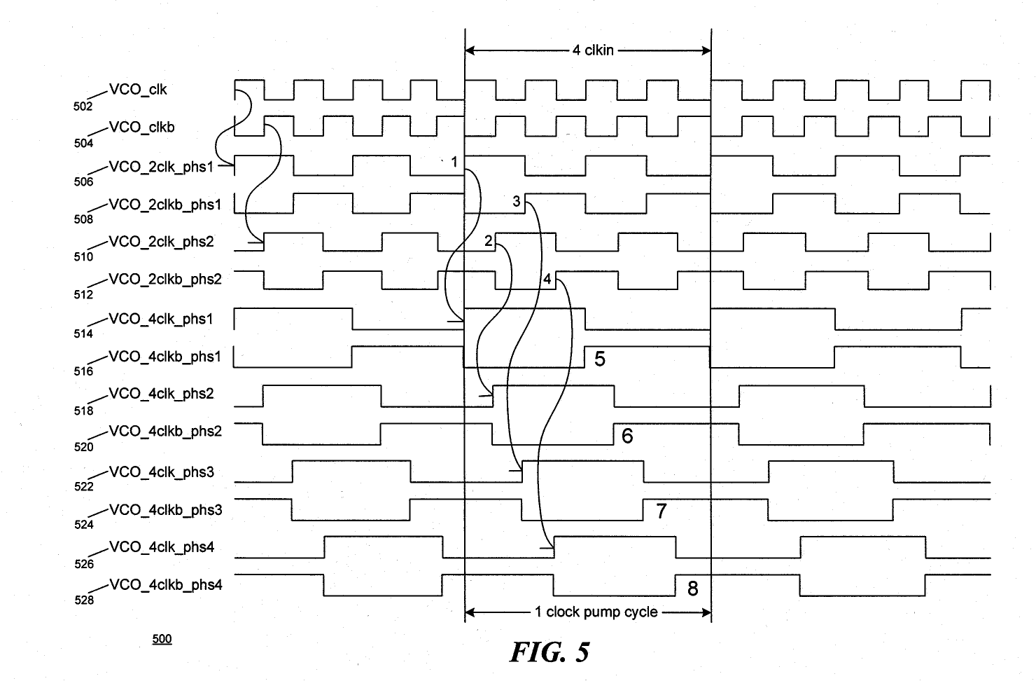

FIG. 4 illustrates a four-phase generator circuit 400 implemented using D flip-flops. Of course, it will be appreciated that the four-phase generator circuit 400 could also be implemented using other memory components. For example, the four-phase generator 400 could be implemented using SR flip-flops, JK flip-flops, or T flip-flops. FIG. 5 illustrates an example timing diagram 500 of the signals associated with the four-phase generator 400. The operation of the four-phase generator 400 will be described below with reference to the timing diagram 500 in FIG. 5.

The four-phase generator 400 receives an input clock signal 502 through a clock signal line 402. The clock signal line 402 is connected to the clock input of a D flip-flop 406₁ and to an inverter 404. The inverter 404 outputs an inverted clock signal 504, which is provided to the clock input of the D flip-flop 406₂. Although not shown here, the D flip-flops may be configured with an initial state to set the starting value of the output. This may be done by providing initial high voltage or ground connection to the D inputs of the D flip-flops 406₁ and 406₂, or by providing an initialization signal to the set or clear terminals of the D flip-flops 406₁ and 406₂. In the example timing diagram shown in FIG. 5, the initial value is the high value. In the timing diagram 500, the D flip-flops 406₁ and 406₂ are triggered by a rising edge of the input clock. However, the flip-flops could also be configured to be triggered by a falling edge or by a specified voltage level.

The D flip-flops 406₁ and 406₂ are configured with the inverted output Q̅ connected as feedback to the individual flip-flop's D input. Thus, when the D flip-flop 406₁ detects a rising edge in the input clock signal 502, it sets the Q signal (signal 506 in FIG. 5) equal to the current input to D. The Q̅ output from D flip-flop 406₁ (signal 508 in FIG. 5) is provided as the new input to the D input. Thus, as shown in FIG. 5, the output signal 506 changes value at the end of every full cycle of the input clock signal 502. This results in a clock signal having double the period of the input clock signal 502. The Q̅ signal 508 from D flip-flop 406₁ is then effectively a clock signal delayed by a half-cycle with respect to the signal 506.

D flip-flop 406₂ functions similarly. However, the flop-flop 406₂ is driven by the inverted clock signal 504 output from the inverter 404. As shown in FIG. 5, the input signal 504 to D flip-flop 406₂ is equal to the input signal 502 delayed by a half cycle. Thus, the output signal 510 from the Q output of D flip-flop 406₂ is equal to the output signal 506 from the Q output of D flip-flop 406₁, but is delayed by a half cycle of the input clock signal 502 (and a quarter cycle of the output signal 506). Similarly, the output signal 512 from the Q̅ output of D flip-flop 406₁ is equal to the output signal 508 from the Q̅ output of D flip-flop 406₁, but delayed by a quarter cycle.

Each of the outputs Q and Q̅ from D flip-flops 406₁ and 406₂ is connected to the clock input of a second stage D flip-flop 408₁-408₄. The D flip-flops 408₁-408₄ are configured similarly to D flip-flops 406₁ and 406₂, with the Q̅ output provided as feedback to the D input of the same flip-flop. The Q outputs are connected to buffers 410₁-410₄. The buffers output clock signals 104₁-104₄, which are provided to the charge pumps 104₁-104₄ of FIG. 3.

As discussed above, the feedback configuration for the D flip-flops 408₁-408₄ results in an output signal having a frequency equal to half that of the input signal. For example, signal 506 is generated from the Q output of D flip-flop 406₁ and provided to the clock input of D flip-flop 408₂. As shown by arrow 1 in FIG. 5, the D flip-flop 408₂ outputs signals 514 and 516 from its Q and Q̅ outputs, respectively. Signal 514 is a clock signal having half the frequency of signal 506 and a quarter the frequency of the input clock signal 502. Similarly, signals 508, 510, and 512 are provided to the second stage D flip-flops 408₁-408₄ to generate output signals 522, 518, and 526, respectively. The output clock signals 514, 518, 522, and 526 are provided to the buffers 410₁-410₄, which generate the clock signals 104. As shown in FIG. 5, the output signals have equal frequency and are delayed by one-eighth of a cycle with respect to each other.

One skilled in the art will appreciate that similar configurations could be used to generate additional clock signals. For example, the circuit 400 could be used as an eight-phase generator by connecting the Q̅ outputs of the D flip-flops 408₁-408₄ to additional buffers to generate a second set of clock signals that are delayed with respect to each other.

One skilled in the art will also appreciate that the four-phase generator 400 is equivalent to a finite state machine configured to generate a set of signals on every input clock pulse from the VCO 302. Thus, the generator circuit 400 could also be implemented using other methods that are well known to produce finite state machines. For example, the circuit 400 could also be implemented using a microcontroller digitally programmed to generate the multiple clock signals. Alternatively, the system could also be configured to use spread spectrum techniques to convert the clock signal received from the VCO 302 into a set of clock signals 104₁-104ₙ that are offset in time and can be provided to the charge pumps 106₁-106ₙ.

From the foregoing, it will be appreciated that specific embodiments of the invention have been described herein for purposes of illustration, but that various modifications may be made without deviating from the spirit and scope of the invention. Accordingly, the invention is not limited except as by the appended claims.

I/We claim:

1. An apparatus for converting power, comprising:
a plurality of charge pumps, wherein each charge pump is configured to generate an output voltage in response to an input control signal and an input power supply;
a controller signal generator configured to generate a plurality of control signals, wherein the generated control signals have edges spaced apart in time and wherein the multiple control signals are provided as input control signals of the plurality of charge pumps.

2. The apparatus of claim 1, wherein the controller signal generator comprises a ring oscillator having multiple stages and wherein the outputs of individual stages are provided as the multiple control signals.

3. The apparatus of claim 1, wherein the controller signal generator comprises a ring oscillator having a plurality of inverters connected in a ring and wherein the outputs of individual inverters of the plurality of inverters are provided as the multiple control signals.

4. The apparatus of claim 1, wherein the controller signal generator comprises:
a clock signal generator configured to generate a clock signal; and
a multi-phase divider configured to generate a plurality of output control signals based on the clock signal and to provide the plurality of output control signals as the multiple control signals.

5. The apparatus of claim 1, wherein the controller signal generator comprises:
a clock signal generator configured to generate a clock signal; and
a multi-phase divider configured to generate a plurality of output control signals based on the clock signal and to provide the plurality of output control signals as the multiple control signals, wherein the multi-phase divider comprises a finite state machine.

6. The apparatus of claim 1, wherein the controller signal generator comprises:
a clock signal generator configured to generate a clock signal; and
a multi-phase divider configured to generate a plurality of output control signals based on the clock signal and to provide the plurality of output control signals as the multiple control signals, wherein the multi-phase divider comprises a finite state machine having a plurality of delay components.

7. The apparatus of claim 6, wherein the delay components are D flip-flops.

8. The apparatus of claim 1, wherein the controller signal generator comprises a spread spectrum clock signal generator.

9. The apparatus of claim 1, further comprising a comparison circuit configured to receive a reference signal and a feedback signal representative of the output voltage and to provide an error signal based on a comparison between the reference signal and the feedback signal.

10. An apparatus for converting power, comprising:
a power converter controller configured to control multiple charge pump circuits, including:
a controller signal generator configured to generate multiple control signals, wherein the generated control signals have edges spaced apart in time.

11. The apparatus of claim 10, wherein the controller signal generator comprises a ring oscillator having a plurality of inverters connected in a ring and wherein the outputs of individual inverters of the plurality of inverters are provided as the multiple control signals.

12. The apparatus of claim 10, wherein the controller signal generator comprises a ring oscillator having multiple stages and wherein outputs of individual stages of the multiple stages are provided as the multiple control signals.

13. The apparatus of claim 10, wherein the controller signal generator comprises:
a clock signal generator configured to generate a clock signal; and
a multi-phase divider configured to generate a plurality of output control signals based on the clock signal and to provide the plurality of output control signals as the multiple control signals.

14. The apparatus of claim 10, wherein the controller signal generator comprises:
a clock signal generator configured to generate a clock signal; and
a multi-phase divider configured to generate a plurality of output control signals based on the clock signal and to provide the plurality of output control signals as the multiple control signals, wherein the multi-phase divider comprises a finite state machine.

15. The apparatus of claim 10, wherein the controller signal generator comprises:
a clock signal generator configured to generate a clock signal; and
a multi-phase divider configured to generate a plurality of output control signals based on the clock signal and to provide the plurality of output control signals as the multiple control signals, wherein the multi-phase divider comprises a finite state machine having a plurality of delay components.

16. The apparatus of claim 15, wherein the delay components are JK flip-flops.

17. The apparatus of claim 10, wherein the controller signal generator comprises a spread spectrum clock signal generator.

18. The apparatus of claim 10, further comprising a comparison circuit configured to receive a reference signal and a feedback signal representative of the output voltage and to provide an error signal based on a comparison between the reference signal and the feedback signal.

19. An apparatus for converting power, comprising:
a first means for selectively storing energy;
a second means for selectively storing energy; and
a control means for controlling the first means and the second means, wherein the control means controls the first means and the second means such that charging of the first means is offset by a predetermined time span from charging of the second means.

20. The apparatus of claim 19, wherein the control means comprises a control signal generation means for generating a plurality of control signals, wherein individual control signals are offset by the predetermined time span from other control signals of the plurality of control signals.

21. The apparatus of claim 19, wherein the control means further comprises:
a control signal generation means for generating a first control signal; and
a signal dividing means for generating a plurality of control signals based on the first control signal, wherein individual control signals are offset by the predetermined time span from other control signals of the plurality of control signals.

22. The apparatus of claim 19, further comprising:
a means for comparing an output of the first means and the second means to a reference value; and
a means for providing an error signal based on the comparison.
